(19) United States
(12) Patent Application Publication
(10) Pub. No.: US 2006/0244114 A1
(43) Pub. Date: Nov. 2, 2006

(54) Systems, methods, and apparatus for connecting a set of contacts on an integrated circuit to a flex circuit via a contact beam

(75) Inventor: Paul Goodwin, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/116,981

(22) Filed: Apr. 28, 2005

(51) Int. Cl. H01L 23/02

(52) U.S. Cl. 257/678

(57) ABSTRACT

Systems, methods, and apparatus for connecting a set of contacts on an integrated circuit to a flex circuit via a contact beam are provided. An exemplary chip-scale packaged (CSP) device comprising an integrated circuit having at least one major surface, the at least one major surface having a set of contacts, is provided. The CSP device may further comprise a flex circuit attached to at least a portion of the at least one major surface of the integrated circuit. The flex circuit may further comprise a first conductive layer for connecting a first CSP contact and a second conductive layer for connecting a second CSP contact. The CSP device may further comprise a preferably pre-stressed beam for connecting at least one signal CSP contact to at least one of the set of contacts on the at least one major surface of the integrated circuit.

### TECHNICAL FIELD

The present invention relates to aggregating integrated circuits, and, in particular, to systems, methods, and apparatus for connecting a set of contacts on an integrated circuit to a flex circuit via a pre-stressed contact beam.

### BACKGROUND OF THE INVENTION

A variety of techniques are used to stack packaged integrated circuits. Some methods require special packages, while other techniques stack conventional packages. In some stacks, the leads of the packaged integrated circuits are used to create a stack, while in other systems, added structures such as rails provide all or part of the interconnection between packages. In still other techniques, flexible conductors with certain characteristics are used to selectively interconnect packaged integrated circuits.

The predominant package configuration employed during the past decade has encapsulated an integrated circuit (IC) in a plastic surround typically having a rectangular configuration. The enveloped integrated circuit is connected to the application environment through leads emergent from the edge periphery of the plastic encapsulation. Such “leaded packages” have been the constituent elements most commonly employed by techniques for stacking packaged integrated circuits.

Leaded packages play an important role in electronics, but efforts to miniaturize electronic components and assemblies have driven development of technologies that preserve circuit board surface area. Because leaded packages have leads emergent from peripheral sides of the package, leaded packages occupy more than a minimal amount of circuit board surface area. Consequently, alternatives to leaded packages known as chip-scale packaged (“CSP”) devices have recently gained market share.

CSP refers generally to packages that provide connection to an integrated circuit through a set of contacts (often embodied as “bumps” or “balls”) arrayed across a major surface of the package. Instead of leads emergent from a peripheral side of the package, contacts are placed on a major surface and typically emerge from the planar bottom surface of the package.

CSP has enabled reductions in size and weight parameters for many applications. For example, micro ball grid array for flash and SRAM and wirebond on tape or rigid laminate CSPs for SRAM or EEPROM have been employed in a variety of applications. CSP is a broad category including a variety of packages from near chip scale to die-sized packages such as the die sized ball grid array (DSBGA) recently described in proposed JEDEC standard 95-1 for DSBGA.

In integrated circuits mounted in a CSP package, conventionally, electrical signals are routed from a contact on a BGA, for example, to a contact for a bond on a die using a trace. In some instances, for power and ground signals the trace may be a narrow trace or an entire plane that connects all power or all ground contacts. Conventional packaging techniques for integrated circuits, however, have several problems.

Such problems include power delivery issues, which are further exacerbated by the CSP package overhang. In particular, the CSP package overhang results in bypass capacitors being placed further away from the power pins on integrated circuits, such as DRAMs.

What is needed, therefore, are systems, methods, and apparatus for connecting a set of contacts on an integrated circuit to a flex circuit via a pre-stressed contact beam.

### SUMMARY OF THE INVENTION

Consistent with the present invention, systems, apparatus, and methods for connecting a set of contacts on an integrated circuit to a flex circuit via a pre-stressed contact beam are provided. Thus, for example, bonding pads on an integrated circuit, such as a DRAM, may be connected to contacts on a flex circuit.

In one embodiment of the invention, a chip-scale packaged (CSP) device comprising an integrated circuit having at least one major surface, where the at least one major surface has a set of contacts is provided. The CSP device may further comprise flex circuitry attached to at least a portion of the at least one major surface of the integrated circuit. The flex circuitry may further comprise a first conductive layer for connecting a first CSP contact and a second conductive layer for connecting a second CSP contact. The CSP device may further comprise a preferably pre-stressed beam for connecting at least one signal CSP contact to at least one of the set of contacts on the at least one major surface of the integrated circuit.

In another embodiment of the invention, a method for assembling a CSP device comprising an integrated circuit having at least one major surface, is provided. The method may include pre-stressing a plurality of contact beams located on a flex circuit configured to connect a set of signal contacts to a set of contacts on the integrated circuit. The method may also include, pre-treating the plurality of contact beams with a malleable material and aligning the contact beams with the set of contacts on the integrated circuit. The method may further include re-flowing the malleable material to form a connection between the set of signal contacts and the set of contacts on the integrated circuit. dr

### SUMMARY OF THE DRAWINGS

FIG. 1 is a cross-section view of a chip scale packaged (CSP) device, consistent with one embodiment of the invention;

FIG. 2 is top view of a flex circuit, consistent with another embodiment of the invention;

FIG. 3 is an end view of another exemplary CSP device, consistent with another embodiment of the invention;

FIG. 4 is a top view of a semiconductor die;

FIG. 5 is an end view of a high density module, consistent with another embodiment of the invention; and

FIG. 6 is a flow chart of an exemplary method for assembling a CSP device, consistent with another embodiment of the invention.

### DESCRIPTION OF PREFERRED EMBODIMENTS

Systems, methods, and apparatus for connecting a set of contacts on an integrated circuit to a flex circuit via a pre-stressed contact beam are provided. An exemplary chip-scale packaged (CSP) device comprising an integrated circuit having at least one major surface, the at least one major surface having a set of contacts, is provided. The CSP device may further comprise a flex circuit attached to at least a portion of the at least one major surface of the integrated circuit. The flex circuit may further comprise a first conductive layer for connecting a first CSP contact and a second conductive layer for connecting a second CSP contact. The CSP device may further comprise a pre-stressed beam for connecting at least one signal CSP contact to at least one of the set of contacts on the at least one major surface of the integrated circuit.

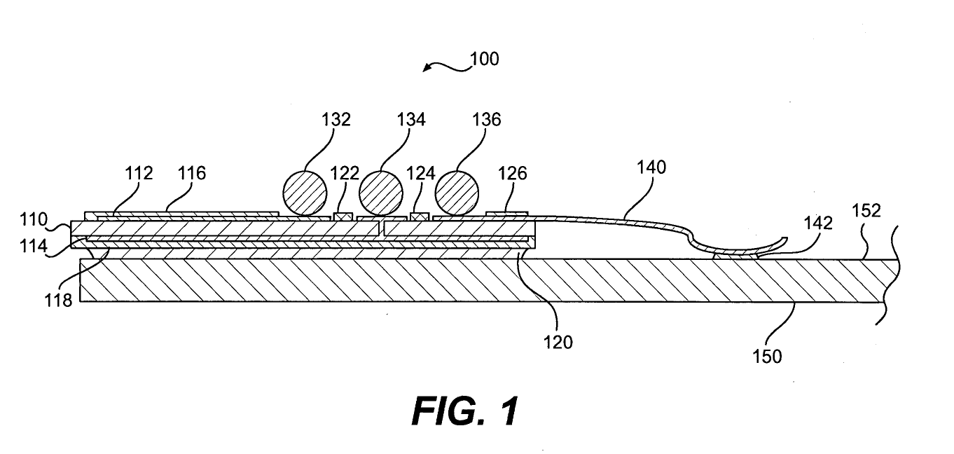

FIG. 1 is a cross-section view of a chip-scale packaged (CSP) device devised in accordance with an embodiment of the present invention. Exemplary CSP device 100 may include an integrated circuit 150 attached to a flex circuit 110. Portions of flex circuit 110 may be fixed to a surface of integrated circuit 150 by an adhesive 120, such as a tape adhesive, which may be a liquid adhesive or may be placed in discrete locations across the package. Adhesive 120 may be thermally conductive and adhesives that include a flux may be used. Flex circuit 110 may, preferably, be a multi-layer flexible circuit structure that has at least two conductive layers. The conductive layers may be metal or alloy. A flex circuit may have a certain shape, for example, rectangular. The flex circuit may also be folded or bent based on the configuration selected for the flex circuit and a CSP device and/or package that may be constructed.

CSP devices and/or packages of a variety of types and configurations such as, for example, those that are die-sized, as well those that are near chip-scale as well as the variety of ball grid array packages known in the art, may be used consistent with various embodiments of the invention. Collectively, these will be known herein as chip-scale packaged (CSP) devices and various embodiments will be described in terms of CSPs, but the particular configurations used in the explanatory figures are not, however, to be construed as limiting. By way of a non-limiting example, the cross-section view of FIG. 1 corresponds to a portion of a CSP device of a particular profile, but it should be understood that the figures are exemplary only. Embodiments of the invention may be employed to advantage in a wide range of CSP configurations available in the art where an array of connective elements is emergent from at least one major surface.

Typical CSPs, such as, for example, ball-grid-array (“BGA”), micro-ball-grid array, and fine-pitch ball grid array (“FBGA”) packages have an array of connective contacts embodied, for example, as leads, bumps, solder balls, or balls that extend from lower surface of a plastic casing in any of several patterns and pitches. An external portion of the connective contacts is often finished with a ball of solder.

As shown in FIG. 1, flex circuit 110 may include a first conductive layer 112 and a second conductive layer 114. By way of a non-limiting example, large portions of first conductive layer 112 may correspond to a power plane and a large portions of second conductive layer 114 may correspond to a ground plane. In one embodiment, first conductive layer 112 connects to a first CSP contact 132. By way of a non-limiting example, first CSP contact 132 may correspond to a power contact, such as a power ball. Second conductive layer 114 connects to a second CSP contact 134. By way of a non-limiting example, second CSP contact may correspond to a ground contact, such as a ground ball.

Flex circuit 110 may further include a first outer cover coat 116 and a second outer cover coat 118. In one embodiment, these coats may provide electrical and thermal insulation. In addition, flex circuit 110 may include other elements for providing thermal and/or electrical insulation, such as elements 122, 124, and 126. Although flex circuit 110 is shown to include these elements, any of these may be omitted and/or conversely other elements may be added.

In this embodiment, flex circuit 110 includes a contact beam 140, which connects a signal CSP contact 136 to a contact 142 on integrated circuit 150. By way of a non-limiting example, contact beam 140 may be pre-stressed such that it puts a downward pressure on contact 142. Contact beam 140 may also be shaped to connect with contact 142. For example, contact beam 140 may have a shape that is particularly suited to form a good contact with contact 142 located on integrated circuit 150. Further, contact beam 140 may be pre-treated with a malleable material, such as solder. The malleable material may be reflowed by thermally recycling CSP device 100 or by ultrasonically vibrating CSP device 100. Indeed, other suitable techniques may also be used.

In this embodiment, contact beam 140 has a curved end in touching contact 42. Not all embodiments require such a curve. Some embodiments may have an end without the depicted upward curve. The depicted upward curve preferably ensures smooth contact during assembly of device 100. In a preferred method, before assembly, the lowest part of contact 140 is offset slightly lower, by a few microns, relative to the flexible circuit. Integrated circuit 150 is placed in the depicted position abutting contact 140 and preferably exerts a displacing force resisted by a spring tension in contact 140. Such spring resistance may help ensure electrical connection and improves reliability.

In this embodiment, contact beam 140 is attached to CSP contact 136. Other embodiments may not have such a connection, but may have other connections to contact beam 140. For example, contact beam 140 may be an extension of a conductive layer such as conductive layer 112, and connection may be made through traces at the conductive layer to a CSP not adjacent to contact beam 140. Other embodiments may have a flex circuit 110 connecting multiple dies in a stacked disposition or side-by-side system-in-package disposition. Such systems may have die-to-die connections implemented with contact beams according to the various embodiments. Other embodiments may make component-to-component connections or exterior connections between different parts of a component using contact beams.

In FIG. 1, a flex circuit (“flex”, “flex circuit” or “flexible circuit structure”) 110 is shown attached to an integrated circuit 150. Although not shown in FIG. 1, flex circuit 110 may also include module contacts, which may be used to connect the flex circuit to other CSP devices, modules, and/or an application environment, such as a PWB. Any rigid, flexible, or conformable substrate with one or more conductive layer capability may be used as a flex circuit in the invention. Although the entire flex circuit may be flexible, a PCB structure made flexible in certain areas to allow conformability around an integrated circuit 150 and rigid in other areas for planarity along CSP surfaces may be employed as an alternative flex circuit in the present invention. For example, structures known as rigid-flex may be employed. Although FIG. 1 shows only one flex circuit 110, more than one flex circuit may be used.

Contact beam 140 is in the depicted preferred embodiment an extended portion of a conductive layer of flex circuit 110. Other embodiments may have other constructions for contact beam 140. For example, a separate piece may be attached to flex circuit 110.

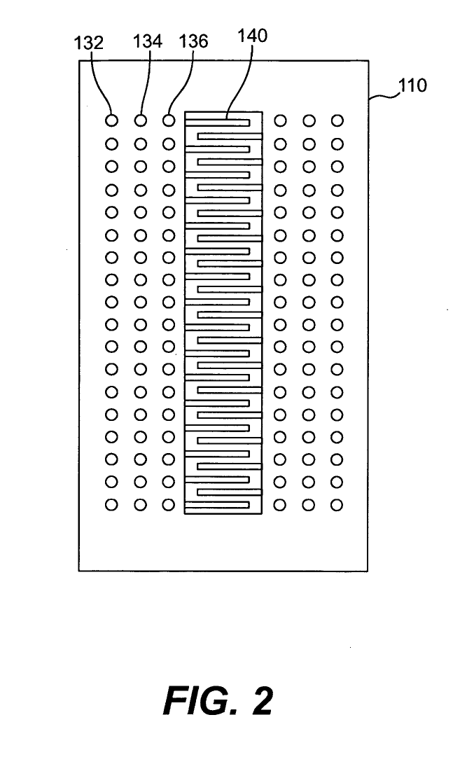

FIG. 2 is a top view of a flex circuit, consistent with another embodiment of the invention. In this example embodiment, flex circuit 110 includes CSP contacts 132, 134, and 136. Flex circuit 110 further includes contact beam 140, which may be arranged as shown in FIG. 2.

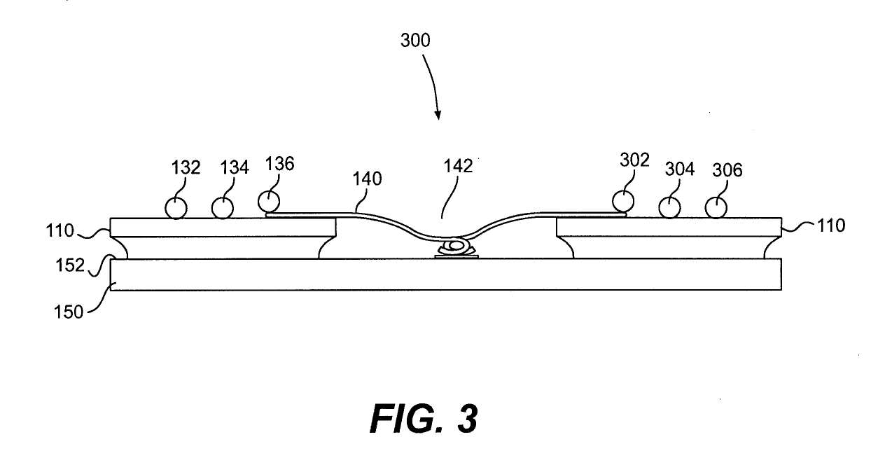

FIG. 3 is an end view of another exemplary CSP device, consistent with another embodiment of the invention. In this embodiment CSP device 300 includes two flex circuits 110 attached to at least a portion of a major surface of the depicted integrated circuit 150. In this embodiment, contact beams 140 have hooked ends abutting contact pads on the integrated circuit 150. In an alternative embodiment, one contact beams 140 having a downwardly-deformed central portion may be used to connect to both a first set of CSP contacts 132, 134, 136 and a second set of CSP contacts 302, 304, and 306 to a set of contacts on integrated circuit 150. Preferably, interconnections made selectively. That is, a selected set of contacts on an integrated circuit (such as, 150) are connected to a respective selected CSP contacts.

Other embodiments may have other shapes of contact beams, such as, for example, beams that connect to flex circuit portion at each end of the beam, with a curved portion in the middle for abutting the die. Still other embodiments may include contact beams positioned to abut and connect to peripheral contact pads on a die. The preferred die contact pad location is central and not peripheral.

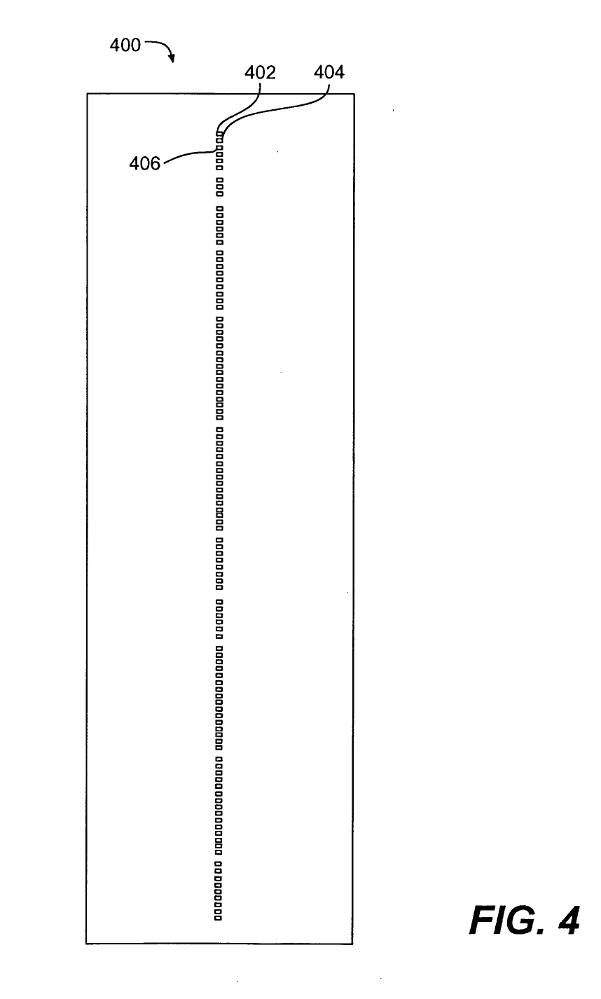

FIG. 4 is top view of a semiconductor die 400. Semiconductor die 400 may include contacts, 402, 404, and 406, such as pads, which could be used to connect the die to form a CSP device, for example.

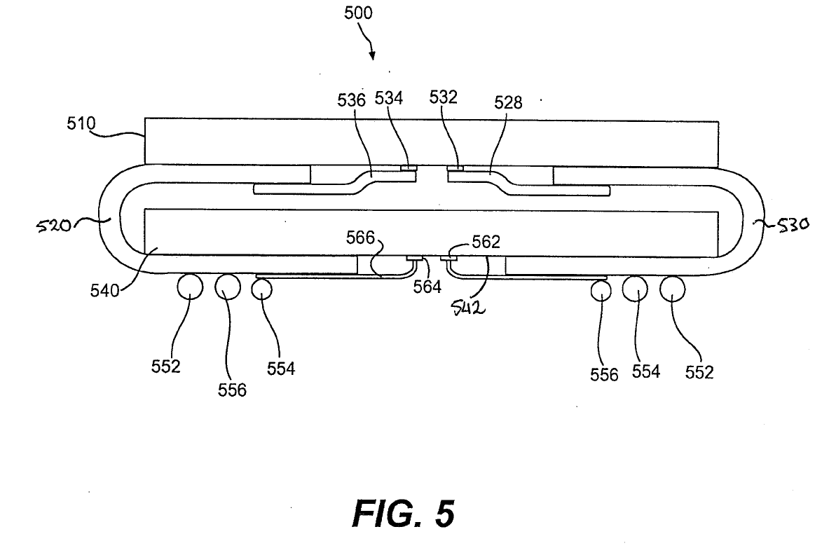

FIG. 5 is an end view of an exemplary high-density module 500 consistent with another embodiment of the invention. By way of a non-limiting example, high density module 500 may include multiple integrated circuits, such as 510, and 540 stacked to form a module. Integrated circuits 510, and 540 may be interconnected using flex circuits, such as 520 and 530. Thus for example, flex circuits 520 and 530 may be attached via an adhesive to a surface of integrated circuit 510.

Each of these flex circuits (520 and 530) may include elements similar to as shown in FIG. 1. By way of a non-limiting example, these elements may include CSP contacts 522, 524, and 526 and a pre-stressed contact beam 528. As explained above with respect to FIG. 1, pre-stressed contact beam 528 may be used to form a connection with at least one contact 532 on a surface 512 of integrated circuit 510. Similarly, pre-stressed contact beam 536 may be used to form a connection with contact 534 on integrated circuit 510. Further, high-density module 500 may include another integrated circuit 540 having contacts 562 and 564 on a surface 542, for example. The lower depicted set of contact beams 566 are shown having a configuration with the end of the respective beams abutting the contacts 562 and 564. The upper depicted set of contact beams 536 and 528 are shown as thicker pieces without curved ends. Such pieces may, in some embodiments, be assembled from a separate contact beam element not expressed as part of a conductive layer of the respective flexible circuits. A conductive layer portion is used, however, in the preferred embodiments.

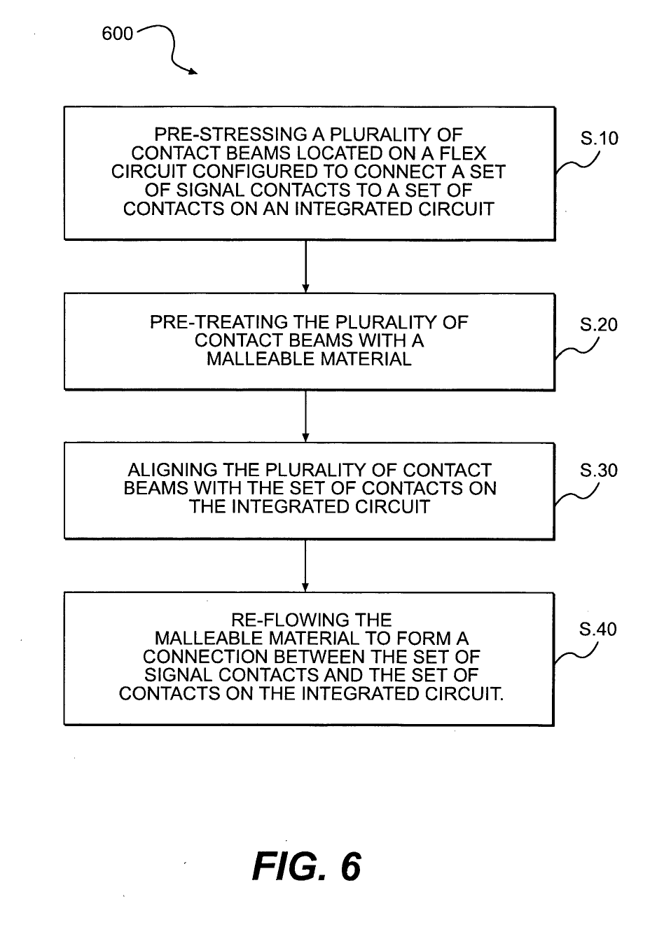

FIG. 6 is a flow chart 600 of an exemplary method for assembling a CSP device, consistent with another embodiment of the invention. The method may include pre-stressing a plurality of contact beams located on a flex circuit configured to connect a set of signal contacts to a set of contacts on the integrated circuit (step S.10). As used herein the term “pre-stressing” refers to a creating the downward bend in contact 140 to make the transition from the upper depicted level of flex circuit 110 to the level of contact pad 142 (as seen, for example, in FIG. 1). Pre-stressing may also include the formation of an upward curve or a looping curve such as those depicted in FIG. 1 and FIG. 3. Preferably, pre-stressing produces an appropriately-shaped contact with enough rigidity to provide resistive force against the die.

The method may also include, pre-treating the plurality of contact beams with a malleable material (step S.20). In one embodiment, as part of this step the plurality of contact beams may be pre-treated with a reasonable malleable material, such as solder. As used here in the term “pre-treating” refers to coating with the selected material before assembly. Such coating may be accomplished with method using, for example, solder paste or a solder tinning process.

The method may further include aligning the contact beams with the set of contacts on the integrated circuit (step S.30).

The method may further include re-flowing the malleable material to form a connection between the set of signal contacts and the set of contacts on the integrated circuit (step S.40). In one embodiment, the malleable material may be re-flowed by thermally recycling the CSP device. Alternatively and/or additionally, re-flowing may be accomplished by ultrasonically vibrating the CSP device. Ultrasonic vibration is preferred. Other methods of connection that do not involve solder or other material may be used. For example, metallic bonding techniques such as ultrasonic welds that do not employ solder may be used. Other assembly methods may be used. For example, contact beam 140 may be assembled with flex circuit 110 from separate pieces. In another exemplar, flex circuit 110 may be aligned with contact beams 140 extending from flex circuit 110 to a position above pads 142 (FIG. 1). Contact beams 140 may then be bent and attached to contacts 142 by any suitable method such as, for example, ultrasonic vibration and/or soldering.

Although the present invention has been described in detail, it will be apparent to those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A chip-scale packaged (CSP) device comprising:
an integrated circuit having at least one major surface, the at least one major surface having a set of contacts; and
flex circuitry attached to at least a portion of the at least one major surface of the integrated circuit, the flex circuit further comprising a first conductive layer for connecting to a first CSP contact and a second conductive layer for connecting to a second CSP contact and a pre-stressed contact beam for connecting at least one signal CSP contact to at least one of the set of contacts of the integrated circuit.

2. The CSP device of claim 1, wherein the pre-stressed contact beam is shaped to connect with at least one of the set of contacts of the integrated circuit.

3. The CSP device of claim 1, wherein the pre-stressed contact beam is pre-treated with a malleable material.

4. The CSP device of claim 3, wherein the malleable material is solder.

5. The CSP device of claim 3, wherein the malleable material is reflowed by thermally cycling the CSP device.

6. The CSP device of claim 3, wherein the malleable material is reflowed by ultrasonically vibrating the CSP device.

7. The CSP device of claim 1, wherein the first conductive layer corresponds to a power plane and the second conductive layer corresponds to a ground plane.

8. The CSP device of claim 1, wherein the first conductive layer corresponds to a power plane.

9. The CSP device of claim 8, wherein the second conductive layer corresponds to a ground plane.

10. The CSP device of claim 9, wherein the power plane and the ground plane are located in relation to the integrated circuit to provide optimum capacitance within the CSP device.

11. A method for assembling a clip-scale packaged (CSP) device, the CSP device comprising an integrated circuit having at least one major surface, the at least one major surface having a set of contacts the method comprising:
pre-stressing a plurality of contact beams located on a flex circuit configured to connect a set of signal contacts to a set of contacts on the integrated circuit;
pre-treating the plurality of contact beams with a malleable material;
aligning the plurality of contact beams with the set of contacts on the integrated circuit; and
re-flowing the re-flowable malleable material to form a connection between the set of signal contacts and the set of contacts on the integrated circuit.

12. The method of claim 11, wherein re-flowing is accomplished by thermally recycling the CSP device.

13. The method of claim 11, wherein re-flowing is accomplished by ultrasonically vibrating the CSP device.

14. The method of claim 11, wherein the malleable material is a re-flowable malleable material.

15. The method of claim 14, wherein the re-flowable material is solder.

16. A high-density circuit module comprising:
a first integrated circuit having at least one major surface, the at least one major surface having a first set of contacts;
flex circuitry attached to at least a portion of the at least one major surface of the integrated circuit, the flex circuit further comprising a first conductive layer for connecting to a first CSP contact and a second conductive layer for connecting to a second CSP contact, at least one of the conductive layers having an extended contact beam portion connecting the first conductive layer to at least one of the set of contacts of the integrated circuit.

17. The high-density circuit module of claim 16, wherein the pre-stressed contact beam is pre-treated with a malleable material.

18. The high-density circuit module of claim 18, wherein the malleable material is solder.

19. The high-density circuit module of claim 18, wherein the malleable material is reflowed by thermally cycling the CSP device; and
and the high-density circuit module of claim 18, wherein the malleable material is reflowed by ultrasonically vibrating the CSP device.

20. The high-density circuit module of claim 18, further including a second integrated circuit having at least one major surface, the at least one major surface having a second set of contacts, the flex circuit.
